(19) United States
(12) Patent Application Publication
(10) Pub. No.: US 2024/0373720 A1
(43) Pub. Date: Nov. 7, 2024

(54) AUTOMOTIVE LIGHT-EMITTING PANEL AND LIGHT-EMITTING APPARATUS

(71) Applicants: Chengdu BOE Optoelectronics Technology Co., Ltd., Chengdu (CN); BOE Technology Group Co., Ltd., Beijing (CN)

(72) Inventor: Lian XIANG, Beijing (CN)

(73) Assignees: Chengdu BOE Optoelectronics Technology Co., Ltd., Chengdu, SC (CN); BOE Technology Group Co., Ltd., Beijing (CN)

(21) Appl. No.: 18/565,524

(22) PCT Filed: May 17, 2022
(86) PCT No.: PCT/CN2022/093347

§ 371 Date: Nov. 30, 2023

(51) Int. Cl. H10K 59/82; F21S 41/155; F21S 41/19; F21S 43/145; F21S 43/19; F21W 106/00; F21Y 105/18; F21Y 115/15; H10K 59/80

(52) U.S. Cl. CPC H10K 59/82; F21S 41/155; F21S 41/192; F21S 43/145; F21S 43/195; H10K 59/80515; F21W 2106/00; F21Y 2105/18; F21Y 2115/15

(57) ABSTRACT

An automotive light-emitting panel and a light-emitting apparatus are provided. The automotive light-emitting panel includes at least one light-emitting unit provided on a side of a base substrate. The light-emitting unit includes a light-emitting device and a signal distribution line for driving the light-emitting device. The light-emitting device includes a light-emitting electrode, a light-emitting region definition layer, an organic light-emitting layer, and a common electrode which are sequentially stacked on the side of the base substrate. The light-emitting unit further includes a patching line, the signal distribution line is electrically connected to the light-emitting electrode of the light-emitting device through the patching line, and a sheet resistance of the patching line is greater than a sheet resistance of the signal distribution line.

### CROSS REFERENCE TO RELATED APPLICATIONS

The present disclosure is the U.S. national phase application of International Application No. PCT/CN2022/093347 filed on May 17, 2022, the content of which is incorporated herein by reference in its entirety for all purposes.

### TECHNICAL FIELD

The present disclosure relates to the field of lighting technology, in particular to an automotive light-emitting panel and a light-emitting apparatus.

### BACKGROUND

OLED (Organic Light-Emitting Diode) devices have broad application prospects in the field of lighting. However, when OLED devices are applied in the field of automotive lighting, the reliability of OLED devices is difficult to meet the requirements of automotive reliability.

It should be noted that the information disclosed in the above section is only used to enhance the understanding of the background of the present disclosure, and thus can include information that does not constitute the prior art already known to those of ordinary skill in the art.

### SUMMARY

According to one aspect of the present disclosure, an automotive light-emitting panel is provided, and the automotive light-emitting panel includes at least one light-emitting unit arranged on a side of a base substrate, wherein the light-emitting unit includes a light-emitting device and a signal distribution line driving the light-emitting device, and the light-emitting device includes a light-emitting electrode, a light-emitting region definition layer, an organic light-emitting layer, and a common electrode that are sequentially stacked on the side of the base substrate; and wherein the light-emitting unit further includes a patching line, wherein the signal distribution line is electrically connected to the light-emitting electrode of the light-emitting device through the patching line, and a sheet resistance of the patching line is greater than a sheet resistance of the signal distribution line.

According to some embodiments of the present disclosure, the signal distribution line is arranged around the light-emitting electrode.

According to some embodiments of the present disclosure, a width of the patching line is smaller than a width of the signal distribution line.

According to some embodiments of the present disclosure, an orthographic projection of the patching line on the base substrate is located within an orthographic projection of the signal distribution line on the base substrate.

According to some embodiments of the present disclosure, the patching line and the light-emitting electrode are arranged in the same layer.

According to some embodiments of the present disclosure, the automotive light-emitting panel further includes an inorganic insulation layer covering the signal distribution line, wherein the inorganic insulation layer has an opening groove that exposes at least part of the signal distribution line, and the patching line is electrically connected to the signal distribution line through the opening groove.

According to some embodiments of the present disclosure, a length of the patching line is not less than half of a length of the signal distribution line.

According to some embodiments of the present disclosure, the patching line included in the light-emitting unit is multiple patching lines, first ends of the patching lines are electrically connected to the signal distribution line, and second ends of the patching lines are electrically connected to different positions on an edge of the light-emitting electrode.

According to some embodiments of the present disclosure, first ends of at least two of the patching lines are electrically connected to each other and are electrically connected to a same position on the signal distribution line.

According to some embodiments of the present disclosure, the patching lines are electrically connected to different positions on the signal distribution line.

According to some embodiments of the present disclosure, the light-emitting unit further includes an electrode tab connected to the light-emitting electrode, wherein a size of a connection between the electrode tab and the light-emitting electrode is greater than a width of the patching line, and the patching line is electrically connected to the electrode tab.

According to some embodiments of the present disclosure, the electrode tab and the light-emitting electrode are arranged in the same layer.

According to some embodiments of the present disclosure, an edge of the electrode tab includes a first edge connected to the patching line and a second edge connected to the light-emitting electrode, and the first edge is not adjacent to the second edge.

According to some embodiments of the present disclosure, an inorganic insulation layer covering the signal distribution line, wherein the electrode tab overlaps with the signal distribution line, and the electrode tab is insulated with the signal distribution line through the inorganic insulation layer.

According to some embodiments of the present disclosure, the electrode tab connected to the light-emitting electrode is multiple electrode tabs, and the electrode tabs are connected to different positions on an edge of the light-emitting electrode.

According to some embodiments of the present disclosure, the electrode tabs connected to the light-emitting electrode are distributed symmetrically to a symmetrical center, and the symmetrical center coincides with a center of the light-emitting electrode.

According to some embodiments of the present disclosure, the electrode tabs connected to the light-emitting electrode are distributed symmetrically to a rotational center, and the rotational center coincides with a center of the light-emitting electrode.

According to some embodiments of the present disclosure, a number of the electrode tabs connected to the light-emitting electrode is 2-6.

According to some embodiments of the present disclosure, at least one of the light-emitting electrode is polygonal, and the electrode tabs are arranged adjacent to a top corner of the light-emitting electrode.

According to some embodiments of the present disclosure, the automotive light-emitting panel further includes an inorganic insulation layer covering the signal distribution line, wherein the light-emitting region definition layer has multiple light-emitting openings that expose the light-emitting electrode, the inorganic insulation layer has a light output groove, and orthographic projections of the light-emitting openings on the base substrate are located within an orthographic projection of the light output groove on the base substrate.

According to some embodiments of the present disclosure, a material of the signal distribution line is metal or conductive metal oxide, and a material of the light-emitting electrode is conductive metal oxide.

According to another aspect of the present disclosure, a light-emitting apparatus is provided, including the automotive light-emitting panel described above.

It should be understood that the general description above and the detailed description in the following are only illustrative and explanatory, and do not limit the present disclosure.

### BRIEF DESCRIPTION OF THE DRAWINGS

The drawings, which are incorporated in and constitute a part of this specification, illustrate embodiments consistent with the present disclosure and serve together with the specification to explain principles of the present disclosure. It is apparent that the drawings in the following description are only some embodiments of the present disclosure, and for those of ordinary skill in the art, other drawings can also be obtained from these drawings without creative efforts.

FIG. 1-1 is a schematic structural diagram of an automotive light-emitting panel according to embodiments of the present disclosure.

FIGS. 1-2 is a schematic structural diagram of an automotive light-emitting panel according to embodiments of the present disclosure.

FIG. 2 is a schematic structural diagram of a light-emitting unit when cutting along a light-emitting electrode, an electrode tab, and a patching line according to embodiments of the present disclosure.

FIG. 3 is a schematic structural diagram of a light-emitting unit when cutting along a light-emitting electrode and an electrode tab according to embodiments of the present disclosure.

FIG. 4 is a schematic structural diagram of a relative position relationship between a light-emitting electrode, a light-emitting groove, a light-emitting opening, and a signal distribution line according to embodiments of the present disclosure.

FIG. 5 is a schematic structural diagram of a relative position relationship between a light-emitting electrode, a light-emitting groove, a light-emitting opening, and a signal distribution line according to embodiments of the present disclosure.

FIG. 6 is a schematic structural diagram of a light-emitting electrode layer and a signal distribution line in a light-emitting unit according to embodiments of the present disclosure.

FIG. 7 is a schematic structural diagram of a light-emitting electrode layer and a signal distribution line in a light-emitting unit according to embodiments of the present disclosure.

FIG. 8 is a schematic structural diagram of a light-emitting electrode layer and a signal distribution line in a light-emitting unit according to embodiments of the present disclosure.

FIG. 9 is a schematic structural diagram of a light-emitting electrode layer and a signal distribution line in a light-emitting unit according to embodiments of the present disclosure.

FIG. 10 is a schematic structural diagram of a light-emitting electrode layer and a signal distribution line in a light-emitting unit according to embodiments of the present disclosure.

### DETAILED DESCRIPTION

Example embodiments will now be described more fully with reference to the drawings. Example embodiments, however, can be embodied in a variety of forms and should not be construed as being limited to examples set forth herein. Instead, these embodiments are provided so that the present disclosure will be thorough and complete, and will fully convey concepts of the example embodiments to those skilled in the art. The same reference numerals in the drawings represent the same or similar structures, and thus their detailed descriptions will be omitted. In addition, the drawings are only illustrative and are not necessarily drawn to scale.

The terms “a”, “an”, “the”, “said”, and “at least one” are used to indicate the existence of one or more elements/components/etc. The terms “include” and “comprise” are used to indicate open inclusion and refer to the existence of additional elements/components/etc. in addition to the listed elements/components/etc. The terms “first”, “second”, and “third” are only used as markers and are not limited to the quantity of objects.

A structural layer A is located on a side of a structural layer B away from a base substrate, which can be understood as the structural layer A being formed on a side of the structural layer B away from the base substrate. When the structural layer B is a patterned structure, part of the structure of the structural layer A can also be located at the same physical height or lower than the physical height of the structural layer B, where the base substrate is a height reference.

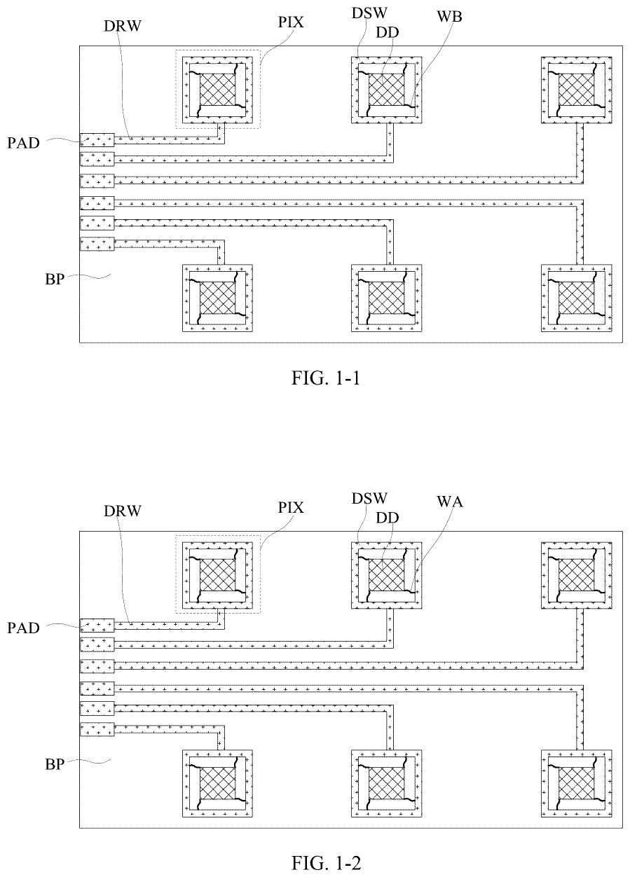

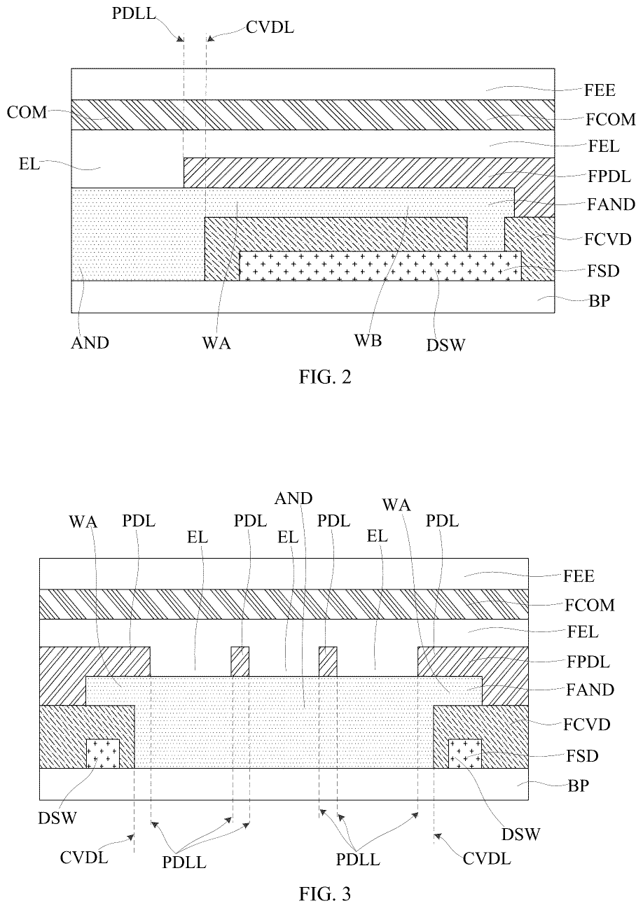

The present disclosure provides an automotive light-emitting panel, as shown in FIGS. 1-1 and 1-2. The automotive light-emitting panel includes at least one light-emitting unit PIX located on a side of the base substrate BP. In some embodiments, any light-emitting unit PIX includes a light-emitting device DD and a signal distribution line DSW driving the light-emitting device DD. Referring to FIGS. 2 and 3, the light-emitting device DD includes a light-emitting electrode AND, a light-emitting region definition layer FPDL, an organic light-emitting layer EL, and a common electrode COM stacked sequentially. The signal distribution line DSW is electrically connected to the light-emitting electrode AND, to load a driving current to the light-emitting device DD.

Referring to FIGS. 1-1 and 1-2, in embodiments of the present disclosure, the automotive light-emitting panel can further include a driving line DRW electrically connected to each signal distribution line DSW in one-by-one correspondence and a driving pin PAD electrically connected to each driving line DRW in one-by-one correspondence. In this way, an external control circuit (such as a circuit board, a flexible circuit board, etc.) can be bound to the driving pin PAD, and then load the driving current to the light-emitting device DD through the driving pin PAD, the driving line DRW, and the signal distribution line DSW, to drive the light-emitting device DD to emit light.

In some embodiments, the brightness of each light-emitting device DD can be controlled by controlling the driving current loaded onto it.

In some embodiments, the macroscopic brightness of the light-emitting device DD can be controlled by controlling a duty ratio of each light-emitting device DD when emits light. In some embodiments, the driving current of each light-emitting device DD is basically the same at each emission.

In some embodiments, other methods can also be used to control the light-emitting brightness of the light-emitting device DD. For example, a strategy of variable driving current and variable duty ratio is applied simultaneously to control the macroscopic brightness of the light-emitting device DD.

In embodiments shown in FIGS. 1-1 and 1-2, one driving line DRW drives one light-emitting unit PIX. It can be understood that in other embodiments of the present disclosure, one driving line DRW can also drive multiple different light-emitting units PIX. For example, one driving line DRW can have multiple branch lines, and each branch line is connected to one light-emitting unit PIX. For another example, one driving line DRW can include multiple sub lines, and the sub lines are alternately connected to the light-emitting units PIX, to enable multiple light-emitting units PIX to be connected in series through the driving line DRW.

According to embodiments of the present disclosure, the driving line DRW, the driving pin PAD, and the signal distribution line DSW can be arranged in the same layer, for example, obtained by patterning the same conductive material layer. In other words, the automotive light-emitting panel can include a driving layer FSD located on a side of the base substrate BP, which includes the driving line DRW, the driving pin PAD, and the signal distribution line DSW. For example, in some embodiments, a conductive material layer can be formed on one side of the base substrate BP, and then the conductive material layer is patterned to obtain the driving layer FSD, which has the aforementioned driving line DRW, driving pin PAD, and signal distribution line DSW. In some embodiments of the present disclosure, other methods can also be used to obtain the driving layer FSD having the driving line DRW, the driving pin PAD, and the signal distribution line DSW. For example, a seed layer can be formed first (such as forming through sputtering a copper metal layer with a thick not exceeding 1 micrometer), and then electrically or chemically plating is performed based on the seed layer to form the required driving layer FSD, or multi-layer wiring can be obtained through multiple deposition etching processes to form the final driving layer FSD, or the driving layer FSD can be directly formed through printing processes. In some embodiments, the driving layer FSD can be made to have a larger thickness, which in turn enables the driving line DRW, the signal distribution line DSW, etc. to have a smaller sheet resistance and larger current transmission capacity, which can meet the high current required for the light-emitting unit PIX to emit light with high brightness.

In some embodiments, the material of the driving layer FSD can be a metallic material, which can include sequentially stacked multi-layer metal structures, for example, a titanium layer/aluminum layer/titanium layer structure, a molybdenum niobium alloy layer/copper layer/molybdenum niobium alloy layer, etc. In some embodiments, the material of the driving layer FSD can be a conductive metal oxide, such as ITO (indium tin oxide).

Referring to FIGS. 2, 3, and 4, in some embodiments of the present disclosure, the automotive light-emitting panel can further include an inorganic insulation layer FCVD located on a side of the driving layer FSD away from the base substrate BP. The inorganic insulation layer FCVD covers the signal distribution line DSW, and the inorganic insulation layer FCVD has an opening groove GG that exposes at least part of the signal distribution line DSW. The light-emitting electrode AND is electrically connected to the signal distribution line DSW through the opening groove GG, for example, directly or indirectly through other structures.

In some embodiments, the inorganic insulation layer FCVD covers each driving line DRW, to avoid short-circuit connections between each film layer of the light-emitting device DD and the driving line DRW.

In some embodiments, the inorganic insulation layer FCVD exposes each driving pin PAD to facilitate binding and connection between external circuits and the driving pin PAD.

In some embodiments, the driving layer FSD can also be provided with a common electrode bonding line and a common voltage pin electrically connected to the common electrode bonding line. The inorganic insulation layer FCVD can expose the common voltage pins and at least part of the common electrode bonding line. In some embodiments, the automotive light-emitting panel is provided with a common electrode layer FCOM, which has a common electrode COM for each light-emitting device DD. The edge of the common electrode layer FCOM can be directly or indirectly connected to the common electrode bonding line. For example, by binding to the common electrode bonding line through the light-emitting electrode layer FAND provided with a light-emitting electrode AND, the common voltage pin can be bound to the external circuit, which allows the external circuit to load common voltage to the common electrode layer FCOM through the common voltage pin and the common electrode bonding line.

In some embodiments, the material of the inorganic insulation layer FCVD is an inorganic insulation material, such as silicon oxide, silicon nitride, silicon oxynitride, and other inorganic materials.

In some embodiments, when preparing the automotive light-emitting panel, the inorganic insulation layer FCVD can be prepared after the preparation of the driving layer FSD has been completed. In some embodiments, an inorganic material layer covering the driving layer FSD can be formed first, and then the inorganic material layer is patterned to form the inorganic insulation layer FCVD. When patterning the inorganic material layer, the main task is to form the required grooves, such as the opening groove GG that exposes the signal distribution line DSW is formed.

Referring to FIGS. 2 and 3, in some embodiments of the present disclosure, the automotive light-emitting panel can include a light-emitting electrode layer FAND, a light-emitting region definition layer FPDL, a light-emitting layer FEL, and a common electrode layer FCOM that are sequentially stacked on a side of the inorganic insulation layer FCVD away from the base substrate BP. The light-emitting electrode layer FAND has a light-emitting electrode AND of the light-emitting device DD. The light-emitting region definition layer FPDL has at least one light-emitting opening that exposes the light-emitting electrode AND. The FEL can cover at least the light-emitting opening to form an organic light-emitting layer EL of the light-emitting device DD, and the common electrode layer FCOM can cover at least the light-emitting opening to form the common electrode COM of the light-emitting device DD. In the automotive light-emitting panel provided by embodiments of the present disclosure, the light-emitting device DD is an OLED (Organic Light-Emitting Diode). Within the range of the light-emitting opening, a light-emitting electrode AND, an organic light-emitting layer EL, and a common electrode COM are stacked sequentially. In this way, the light-emitting region definition layer FPDL defines an actual light-emitting region in the light-emitting device DD by arranging the light-emitting opening. A subunit of the light-emitting device DD is formed at a position corresponding to the light-emitting opening.

In some embodiments, the material of the light-emitting region definition layer FPDL can be selected from PS-PI (polystyrene polyimide). In some embodiments of the present disclosure, the material of the light-emitting region definition layer FPDL can also be selected from other photosensitive polymer materials.

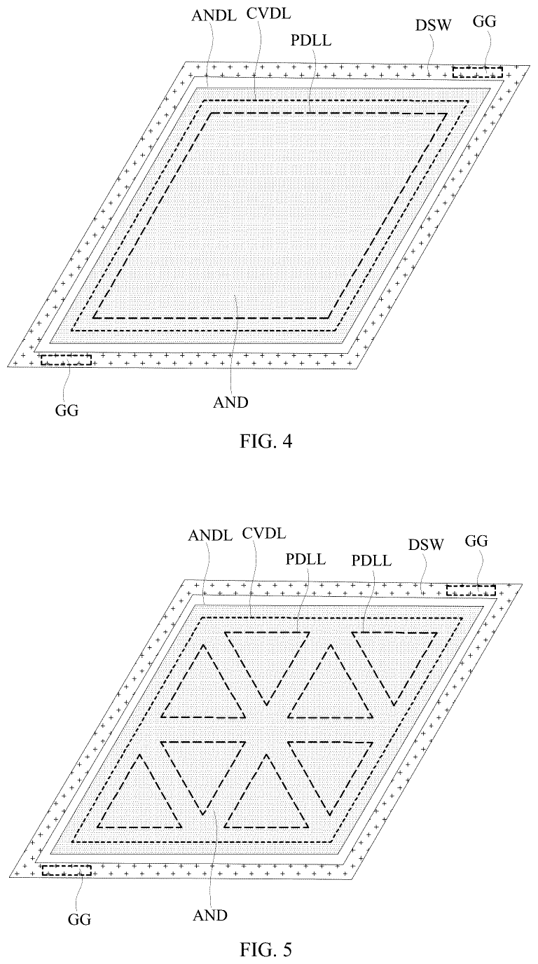

In embodiments in FIGS. 2 to 5, an edge of the light-emitting region definition layer FPDL is illustrated using a line PDLL when the light-emitting opening is formed, which is also an edge of the light-emitting opening. Referring to FIGS. 4 and 5, in each light-emitting device DD, the light-emitting region definition layer FPDL can form one light-emitting opening or multiple different light-emitting openings. When multiple light-emitting openings are formed, the region corresponding to each light-emitting opening forms the subunit of the light-emitting device DD.

According to embodiments of the present disclosure, the number of light-emitting openings in each light-emitting device DD can be arranged according to demands, and the shape and the size of each light-emitting opening can be arranged according to needs. In the automotive light-emitting panel, the number of light-emitting openings for any two light-emitting devices DD can be the same or different. In the same light-emitting device DD, the shape of any two light-emitting openings can be the same or different. According to the design purpose, for example, based on the patterns that need to be presented or various different patterns that can be presented when the light-emitting panel in the vehicle emits light, the number, shape, and arrangement of the light-emitting openings in each light-emitting device DD can be adjusted to meet the requirements of lighting while presenting a specific pattern or patterns.

In some embodiments, as shown in FIG. 4, at least one light-emitting device DD of the automotive light-emitting panel is provided with only one light-emitting opening. The shape of the light-emitting opening can match with the shape of the light-emitting electrode AND. For example, there is a preset spacing between the edge of the light-emitting opening (line PDLL in FIG. 4) and the edge of the light-emitting electrode AND (line ANDL in FIG. 4), which can increase the area of the light-emitting opening when the size of the light-emitting electrode AND is fixed. In other words, the aperture ratio of the automotive light-emitting panel can be improved. This can enable the light-emitting device DD to have a larger light-emitting area and exhibit higher light-emitting brightness, especially improving the macroscopic brightness of the light-emitting device DD. In addition, a lower current density can be used to achieve better macroscopic brightness, which is beneficial for improving the lifespan of the light-emitting device DD. In the present disclosure, the current density of the light-emitting device DD refers to the current density flowing through the organic light-emitting layer EL, rather than the current density on the light-emitting electrode AND or the common electrode COM.

In some embodiments, as shown in FIG. 5, at least one light-emitting device DD of the automotive light-emitting panel is provided with multiple light-emitting openings. The edge of each light-emitting opening is shown as line PDLL in FIG. 5. In embodiments in FIG. 5, the shape of each light-emitting opening is triangular and periodically arranged. In this way, various light-emitting devices DD can present certain patterns or textures while emitting light.

It can be understood that in FIGS. 4 and 5, the pattern of the light-emitting opening is represented as a quadrilateral and a triangle. In some embodiments of the present disclosure, the pattern of the light-emitting opening can be adjusted according to needs. For example, the pattern can be presented as a square, a rectangle, a diamond, a pentagonal star, a regular hexagon, a bar, a zigzag, a star, a crescent, a circle, an ellipse, a flower shape, a straight bar, a curved bar, a letter shape, or other definable patterns, which is not limited in the present disclosure.

It can be understood that in FIGS. 4 and 5, the number of light-emitting openings in each light-emitting device DD is exemplified as 1 or 8. In some embodiments of the present disclosure, the number of light-emitting openings can be other, such as between 1 and 1000.

In some embodiments of the present disclosure, the light-emitting electrode AND can use a transparent electrode, and the common electrode COM can use a reflective electrode with high reflectivity. In this way, the light from the light-emitting device DD can be emitted through the light-emitting electrode AND. In the embodiments, the base substrate BP needs to use a transparent base substrate BP, for example, inorganic transparent materials such as glass, or organic transparent materials such as polyimide, or a combination of inorganic transparent materials and organic transparent materials.

In some embodiments, the material of the base substrate BP can be soda-lime glass, quartz glass, sapphire glass, and other glass materials. In some embodiments, the material of the base substrate BP can be organic materials such as polymethyl methacrylate (PMMA), polyvinyl alcohol (PVA), polyvinyl phenol (PVP), polyether sulfone (PES), polyimide, polyamide, acetal, polycarbonate (PC), polyethylene terephthalate (PET), polyethylene naphthalate (PEN), or a combination of these organic materials.

In some embodiments, the base substrate BP can be a flexible base substrate BP with a polyimide layer, and the automotive light-emitting panel can be a flexible automotive light-emitting panel. For example, the base substrate BP can include stacked polyimide layers and inorganic barrier layers (such as a silicon nitride layer or a silicon oxide layer), with the driving layer FSD located on a side of the inorganic barrier layer away from the polyimide layer. For example, the base substrate BP can include multiple polyimide layers, with an inorganic barrier layer being sandwiched between the polyimide layers, and an inorganic buffer layer (such as a silicon oxide layer) being located at the top layer. The driving layer FSD is located on a side of the inorganic buffer layer away from the polyimide layer. In this way, the mechanical properties of the base substrate BP can be improved, so that the base substrate BP meets the mechanical performance requirements of the automotive light-emitting panel for strength performance, stress performance, and other aspects.

In embodiments of the present disclosure, the light-emitting electrode AND can be a transparent electrode with high transmittance, such as ITO (indium tin oxide). In embodiments of the present disclosure, the common electrode COM can be a metal electrode with high reflectivity, such as a silver electrode, an aluminum electrode, or other thick electrodes. In some embodiments, various common electrodes COM can be connected to each other to form a whole electrode. In other words, the common electrode layer FCOM is a whole electrode surface, and the part where the common electrode layer FCOM overlaps with each light-emitting device DD can serve as the common electrode COM of the light-emitting device DD.

In some embodiments of the present disclosure, the light-emitting electrode AND can also use a reflective electrode, and the common electrode COM can use a transparent electrode. The base substrate BP can also not use a transparent base substrate BP, for example, the material can also be selected from metal materials such as stainless steel, aluminum, nickel, etc.

In some embodiments, the light-emitting electrode AND can be an anode of the light-emitting device DD, and the common electrode COM can be a cathode of the light-emitting device DD. In some embodiments, the light-emitting electrode AND can also be used as the cathode of the light-emitting device DD, and the common electrode COM can be used as the anode of the light-emitting device DD, by changing the film structure of the organic light-emitting layer EL and the driving method of the automotive light-emitting panel.

In some embodiments of the present disclosure, as shown in FIGS. 2 to 5, the inorganic insulation layer FCVD can also be provided with a light output groove. At the light output groove, the inorganic insulation layer FCVD can be completely excavated or thinned. The orthographic projection of the light output groove on the base substrate BP is located within the orthographic projection of the light-emitting electrode AND on the base substrate BP. The orthographic projection of the light-emitting opening on the base substrate BP can be within the orthographic projection of the light output groove on the base substrate BP. In this way, the inorganic insulation layer FCVD between the subunit of the light-emitting device DD and the base substrate BP is thinned or excavated, which can reduce the impact of the inorganic insulation layer FCVD on the light output rate and improve the light output efficiency.

In some embodiments, referring to FIGS. 2 and 3, the edge of the light output groove is represented by a line CVDL, that is, the inorganic insulation layer FCVD is adjacent to the edge of the light output groove. In some embodiments, the light output groove is a through-hole groove, which means that the inorganic insulation layer FCVD in the light output groove is completely excavated.

In some embodiments, referring to FIGS. 4 and 5, the edge of the light output groove is represented by a line CVDL, that is, the inorganic insulation layer FCVD is adjacent to the edge of the light output groove. The edge of the light-emitting opening is represented by a line PDLL, and the edge of the light-emitting electrode AND is represented by a line ANDL. In some embodiments, the light-emitting electrode AND covers the light output groove, causing the light-emitting electrode AND to overlap on the inorganic insulation layer FCVD. The light-emitting opening is within the light output groove.

In some embodiments of the present disclosure, as shown in FIGS. 2 and 3, the light-emitting layer FEL can cover the light-emitting opening, to form an organic light-emitting layer EL of the light-emitting device DD within the light-emitting opening. The organic light-emitting layer EL can include an organic electroluminescent material layer, as well as one or more of a hole injection layer, a hole transport layer, an electron barrier layer, a hole barrier layer, an electron transport layer, and an electron injection layer. Various film layers of the organic light-emitting layer EL can be prepared through evaporation process, and the pattern of each film layer can be defined using a fine metal mask or an open mask during evaporation.

In some embodiments, the automotive light-emitting panel can be a monochromatic light-emitting panel for vehicle, such as the monochromatic light-emitting panel in red, blue, yellow, orange, white, etc. An open mask can be used to prepare the light-emitting layer FEL, which covers the light-emitting region definition layer FPDL and the light-emitting opening. In this way, each subunit of the light-emitting device DD is a subunit of the same color. In some embodiments, a mask (especially a fine metal mask) can also be used to make the light-emitting device DD have different color subunits. By adjusting the ratio between different color subunits, the mixing ratio of different light rays in the light-emitting device DD can be adjusted, to emit the required monochromatic light. Alternatively, a stacked structure can be used to make the subunits of the light-emitting device DD have multiple stacked layers of different organic electroluminescent material layers. By utilizing the different light emitted by different organic electroluminescent material layers, mixed light can be achieved, thereby achieving the emission of the monochromatic light.

In some embodiments, the automotive light-emitting panel is an automotive light-emitting panel that can emit light of multiple different colors, for example, red light or yellow light is emitted according to needs, or the automotive light-emitting panel is an automotive light-emitting panel that can adjust color temperature. At this point, the automotive light-emitting panel requires at least two different color light-emitting units (PIX), which can be controlled to emit light separately or mixed to obtain the required macroscopic light.

In some embodiments of the present disclosure, as shown in FIGS. 1-1 and 1-2, multiple different positions on the edge of the light-emitting electrode AND are electrically connected to the signal distribution line DSW. In this way, the signal distribution line DSW can load current to multiple different positions on the edge of the light-emitting electrode AND, thereby reducing the amount of current flowing into the light-emitting electrode AND at each position, reducing the current density at the local position of the light-emitting electrode AND, and thus avoiding burning problems due to excessive current density at the local position of the light-emitting electrode AND. Not only that, this can also reduce the distance between a near end and a far end of a current inlet (i.e. the position where the current flows into the light-emitting electrode AND) of the light-emitting electrode AND, thereby making the current density at different positions of the light-emitting device DD more uniform, and improving the uniformity of the brightness of the light-emitting device DD at different positions. In the present disclosure, the current density of the light-emitting electrode AND refers to the current density at various positions of the light-emitting electrode AND itself, such as the current density at the edge of the light-emitting electrode AND. The current density of the light-emitting device DD refers to the density of the current flowing through the organic light-emitting layer EL at different positions of the light-emitting device DD. In embodiments described above in the present disclosure, the light-emitting electrode AND is used as the anode for exemplary description. When the light-emitting electrode AND serves as the anode, the current flows from the signal distribution line DSW into the light-emitting electrode AND. It can be understood that when the light-emitting electrode AND serves as the cathode, the current flows from the light-emitting electrode AND into the signal distribution line DSW.

In some embodiments of the present disclosure, the edge of the light-emitting electrode AND can also have only one position electrically connected to the signal distribution line DSW, so that the light-emitting electrode AND can be electrically connected to the signal distribution line DSW.

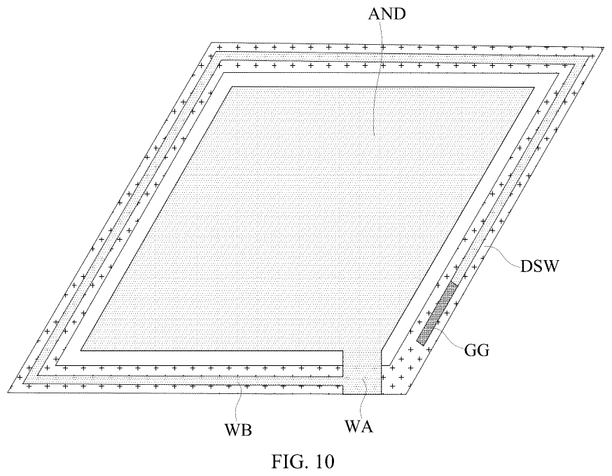

In some embodiments of the present disclosure, the signal distribution line DSW can be arranged around the light-emitting electrode AND. For example, referring to FIGS. 4 and 5, where the signal distribution line DSW surrounds a closed containment cavity. The light-emitting electrode AND of the light-emitting device DD is accommodated in the containment cavity. In embodiments in FIGS. 4 and 5, the signal distribution line DSW is distributed in a quadrilateral ring shape, thereby forming a quadrilateral containment cavity. In some embodiments of the present disclosure, the containment cavity surrounded by the signal distribution line DSW can also be of other shapes. For example, a square containment cavity (see FIGS. 1-2) or a circular containment cavity (see FIG. 9) can be obtained through surrounding by the signal distribution line DSW. In some embodiments of the present disclosure, the containment cavity surrounded by the signal distribution line DSW can also be unclosed, for example, the signal distribution line DSW can be of unclosed shapes such as U-shaped or Y-shaped.

According to embodiments of the present disclosure, as shown in FIGS. 1-1, in the light-emitting unit PIX, the edge of the light-emitting electrode AND of the light-emitting device DD can be electrically connected to the signal distribution line DSW through a patching line WB. In some embodiments, the sheet resistance of the patching line WB is greater than that of the signal distribution line DSW. In this way, the patching line WB can be connected in series as an equivalent resistor between the signal distribution line DSW and the light-emitting device DD. When there is no short circuit fault in the light-emitting device DD, the current can flow normally through the patching line WB without affecting the lighting of the light-emitting device DD. Once there is a short circuit fault in the light-emitting device DD, that is, the common electrode COM and light-emitting electrode AND of the light-emitting device DD are short circuited, the patching line WB can be used as a load, allowing the automotive light-emitting panel to continue to be used instead of being abandoned due to the short circuit, which can improve the reliability of the automotive light-emitting panel and make it meet the requirements of Automotive Grade.

In some embodiments, the light-emitting unit PIX includes multiple patching lines WB, with a first end of each patching line WB being electrically connected to the signal distribution line DSW, and a second end of each patching line WB being electrically connected to different positions on the edge of the light-emitting electrode AND.

In some embodiments of the present disclosure, as shown in FIGS. 1-2, the light-emitting unit PIX further includes therein an electrode tab WA connected to the light-emitting electrode AND. The electrode tab WA is electrically connected to the signal distribution line DSW. In this way, the current of the signal distribution line DSW can be first loaded onto the electrode tab WA, redistributed on the electrode tab WA, and then flowed into the light-emitting electrode AND, to reduce the current density at the current inlet of the light-emitting electrode AND and reduce the risk of burning.

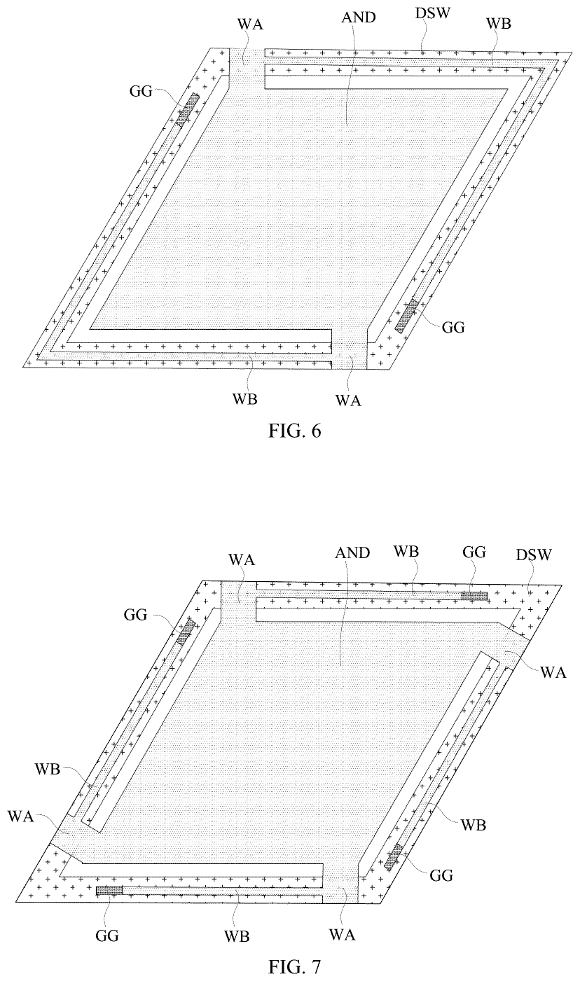

In some embodiments of the present disclosure, as shown in FIGS. 6 to 10, in the light-emitting unit PIX, both the electrode tab WA and the patching line WB can be arranged simultaneously. The electrode tab WA is connected to the edge of the light-emitting electrode AND, with one end of the patching line WB being connected to the electrode tab WA and the other end being connected to the signal distribution line DSW. In this way, the light-emitting unit PIX can have high reliability and low risk of bottom burning.

In some embodiments, as shown in FIGS. 6 to 10, a connection size between the electrode tab WA and the light-emitting electrode AND is greater than a width of the patching line WB. In this way, the current inlet of the light-emitting electrode AND can have a larger width, thereby reducing the risk of burning. At the same time, it can also ensure that the patching line WB has a large equivalent resistance, thereby further improving the reliability of the automotive light-emitting panel.

In some embodiments, referring to FIGS. 6 to 10, an edge of the electrode tab WA includes a first edge connected to the patching line WB and a second edge connected to the light-emitting electrode AND. The first edge is not adjacent to the second edge. In other words, the first edge is the current inlet of the electrode tab WA, the second edge is the current outlet of the electrode tab WA and the current inlet of the light-emitting electrode AND. The current inlet of the electrode tab WA is not adjacent to the current outlet of the electrode tab WA, so that after the current flows into the electrode tab WA from the first edge, there is sufficient space for current redistribution. The redistributed current flows into the light-emitting electrode AND through the second edge, thereby ensuring a decrease in current density flowing into the light-emitting electrode AND.

The electrode tab WA and patching line WB in embodiments of the present disclosure will be further described and explained in the following in conjunction with the drawings.

In some embodiments of the present disclosure, as shown in FIGS. 6 to 9, the light-emitting unit PIX includes multiple electrode tabs WA connected to the light-emitting electrode AND, each of which is electrically connected to the signal distribution line DSW, for example, directly electrically connected to the signal distribution line DSW or transferred to be connected to the signal distribution line DSW through the patching line WB. In some embodiments, the electrode tab WA and the light-emitting electrode AND are arranged in the same layer, that is, the light-emitting electrode layer FAND includes the light-emitting electrode AND and the electrode tab WA connected to the light-emitting electrode AND. The electrode tab WA can protrude from the light-emitting electrode AND to be electrically connected to the signal distribution line DSW, and redistribute the current entering the light-emitting electrode AND, so as to reduce the current density entering the light-emitting electrode AND and reduce the risk of burning of the light-emitting electrode AND. Moreover, this can at least to some extent improve the uniformity of current density at different positions of the light-emitting device DD, thereby improving the brightness uniformity of the light-emitting device DD.

In some embodiments, each electrode tab WA is uniformly or symmetrically distributed along the edge of the light-emitting electrode AND, to further improve the brightness uniformity of the light-emitting device DD. In some embodiments, as shown in FIG. 6, the various electrode tabs WA connected to the light-emitting electrode AND are symmetrically distributed at the center. In some embodiments, a symmetry center coincides with the center of the light-emitting electrode AND. In some embodiments, as shown in FIG. 10, the various electrode tabs WA connected to the light-emitting electrode AND are rotationally symmetric. In some embodiments, a rotational symmetry center coincides with the center of the light-emitting electrode AND. These embodiments can make the current flow into the light-emitting electrode AND more evenly, thereby more effectively improving the uniformity of current density at different positions of the light-emitting device DD and improving the brightness uniformity of the light-emitting device DD.

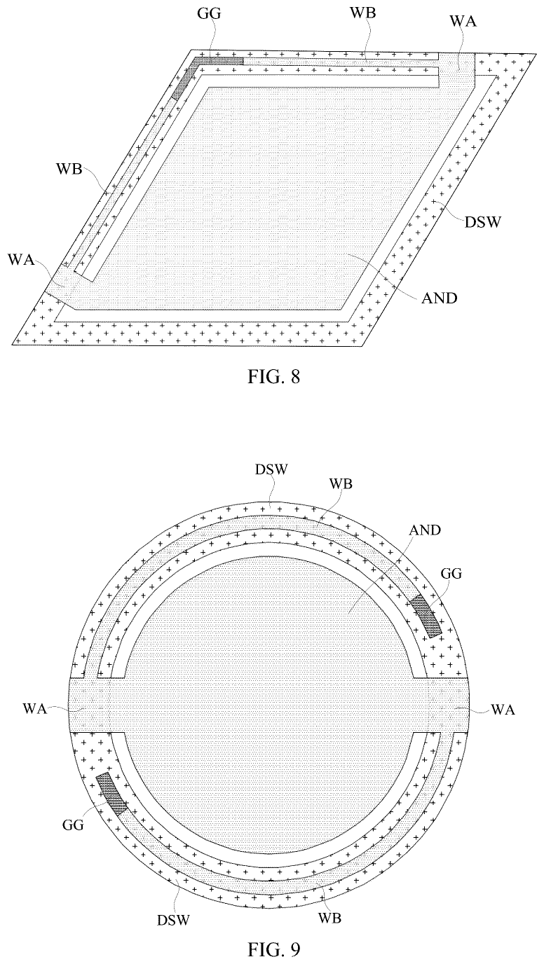

In some embodiments of the present disclosure, as shown in FIG. 8, it is possible for the electrode tab WA not to distribute in a uniform form. In some embodiments, adjacent electrode tabs WA can be separated by a relatively long distance, for example, they can be arranged relative to each other or near different top corners of the light-emitting electrode AND, which can also significantly improve the uniformity of the brightness of the light-emitting device DD.

In some embodiments, the number of electrode tabs WA connected to the same light-emitting electrode AND is 2-6. The more the number of electrode tabs WA connected to the light-emitting electrode AND is, the more uniform the distribution of the electrode tabs WA is, and the better the uniformity of the brightness of the light-emitting device DD is.

In some embodiments of the present disclosure, as shown in FIGS. 6 to 8, at least one of the light-emitting electrodes AND has a polygonal shape. The electrode tab WA is arranged near the top corners of the light-emitting electrode AND. In this way, the problem of low current density at the top corner can be effectively avoided and the uniformity of current distribution can be improved.

According to embodiments of the present disclosure, the light-emitting unit PIX further includes the patching line WB corresponding to each of the electrode tabs WA in one-by-one correspondence. The patching line WB is electrically connected to the signal distribution line DSW, and is electrically connected to the corresponding electrode tab WA. The width of the electrode tab WA is greater than the width of the patching line WB. In some embodiments, the width of the electrode tab WA refers to the size of an edge, among the edges of the electrode tab WA, connected to the light-emitting electrode AND. The width of the patching line WB refers to the size of the orthographic projection of the patching line WB on the base substrate BP in an extension direction perpendicular to the patching line WB.

In this way, the patching line WB has a smaller width and has a certain resistance. If there is a short circuit between the light-emitting electrode AND and the common electrode COM of the light-emitting device DD, the patching line WB can be used as a load due to a certain resistance of the patching line WB, avoiding the entire automotive light-emitting panel from being unusable due to the short circuit of one light-emitting device DD. The width of the electrode tab WA is greater than that of the patching line WB, which enables the current of the patching line WB to be redistributed on the electrode tab WA, allowing the current density to flow into the light-emitting electrode AND of the light-emitting device DD after being reduced, avoiding the burning of the light-emitting electrode AND by high current.

In some embodiments, the width of the electrode tab WA is 2-10 times the width of the patching line WB. In this way, it can be ensured that the electrode tab WA has a larger width and the patching line WB has a larger resistance, thereby achieving a balance between improving the tolerance of the automotive light-emitting panel to short circuit defects of the light-emitting device DD and reducing the risk of burning of the light-emitting electrode AND.

In some embodiments, the sheet resistance of the patching line WB is more than 8 times the sheet resistance of the signal distribution line DSW. For example, the sheet resistance of the signal distribution line DSW is 0.05 Ω/□, and the sheet resistance of the patching line WB is 0.5 Ω/□.

In some embodiments, the patching line WB and the light-emitting electrode AND are arranged in the same layer, that is, both are arranged on the light-emitting electrode layer FAND.

For example, the electrode tab WA, the patching line WB, and the light-emitting electrode AND are arranged in the same layer, that is, they are all arranged on the light-emitting electrode layer FAND. In this way, the light-emitting electrode layer FAND includes the light-emitting electrode AND, the electrode tab WA, and the patching line WB.

According to embodiments of the present disclosure, the electrode tab WA overlaps with the signal distribution line DSW, and the electrode tab WA and the signal distribution line DSW are insulated through the FCVD.

In some embodiments, as shown in FIGS. 3 and 6, the electrode tab WA is located on a side of the inorganic insulation layer FCVD away from the base substrate BP and can extend to overlap with the signal distribution line DSW. A connection location between the electrode tab WA and the patching line WB overlaps with the signal distribution line DSW. In this way, the electrode tab WA and the signal distribution line DSW are insulated through the inorganic insulation layer FCVD. A position on the patching line WB where the current flows into the electrode tab WA is at a certain distance from the light-emitting electrode AND, which allows sufficient space for the current flowing into the electrode tab WA to be redistributed, thereby avoiding current concentration when the current flows from the electrode tab WA to the light-emitting electrode AND.

In some embodiments, as shown in FIGS. 2 and 6, the inorganic insulation layer FCVD is provided with an opening groove GG that exposes the signal distribution line DSW. The patching line WB is arranged on a side of the inorganic insulation layer FCVD away from the base substrate BP and is electrically connected to the signal distribution line DSW through the opening groove GG.

In some embodiments, as shown in FIGS. 6-8, the width of the patching line WB is smaller than the width of the signal distribution line DSW, which increases the resistance of the patching line WB and further improves the tolerance of the automotive light-emitting panel to short circuit defects of the light-emitting device DD.

In some embodiments, the orthographic projection of the patching line WB on the base substrate BP is within the orthographic projection of the signal distribution line DSW on the base substrate BP. In this way, the patching line WB can be distributed along a distribution trajectory of the signal distribution line DSW.

In some embodiment of the present disclosure, each of the patching lines WB is connected to different positions of the signal distribution line DSW.

In some embodiments, the patching line WB extending along the extension trajectory of the signal distribution line DSW is provided between two adjacent electrode tabs WA. One end of the patching line WB is electrically connected to one of the electrode tabs WA, and the other end of the patching line WB is adjacent to the other electrode tab WA and electrically connected to the signal distribution line DSW through the opening groove GG. In this way, each electrode tab WA is electrically connected to the signal distribution line DSW through a patching line WB and an opening groove GG, so that the current flowing out from a single opening groove GG is not too large. The end at which the patching line WB is connected to the signal distribution line DSW through the opening groove GG is adjacent to the other electrode tab WA, which allows the length of the patching line WB to be as long as possible, so that the resistance of the patching line WB is as large as possible. In some embodiments, the distribution trajectory of each patching line WB surrounds the light-emitting electrode AND as a whole.

In some embodiments, as shown in FIG. 6, in a light-emitting unit PIX, the light-emitting electrode layer FAND includes a light-emitting electrode AND and two electrode tabs WA connected to the light-emitting electrode AND, as well as two patching lines WB connected to the two electrode tabs WA in one-by-one correspondence. The inorganic insulation layer FCVD is provided with the opening grooves GG corresponding to the two electrode tabs WA one by one. The patching line WB corresponding to the electrode tab WA extends along the extension trajectory of the signal distribution line DSW, with one end being connected to the corresponding electrode tab WA and the other end being connected to the signal distribution line DSW through the corresponding opening groove GG. In some embodiments, the opening groove GG corresponding to the electrode tab WA is arranged near the other electrode tab WA.

In some embodiments of the present disclosure, at least two first ends of the patching lines WB are electrically connected to each other and electrically connected to the same position of the signal distribution line DSW. For example, two adjacent patching lines WB can be connected to the signal distribution line DSW through the same opening groove GG. In this way, the distribution trajectory of each patching line WB can be able to not necessarily surround the entire light-emitting electrode AND. In some embodiments, the density of the current flowing out of the opening groove GG can be reduced by enlarging the opening groove GG.

In some embodiments, as shown in FIG. 8, in a light-emitting unit PIX, the light-emitting electrode layer FAND includes a light-emitting electrode AND and two electrode tabs WA connected to the light-emitting electrode AND, as well as two patching lines WB connected to the two electrode tabs WA in one-by-one correspondence. The patching line WB extends along the extension trajectory of the signal distribution line DSW. The inorganic insulation layer FCVD is provided with an opening groove GG. The two patching lines WB are electrically connected to their respective electrode tabs WA, and the two patching lines WB are electrically connected to each other to form one patching line WB. The merged patching line WB is electrically connected to the signal distribution line DSW through the opening groove GG.

In some embodiments of the present disclosure, as shown in FIG. 10, the light-emitting electrode AND in the light-emitting unit PIX can also be connected to the signal distribution line DSW through an electrode tab WA. The density of the current flowing into the light-emitting electrode AND can be reduced by increasing the width of the electrode tab WA, for example, making the width of the electrode tab WA greater than the width of the patching line WB. The specific width of the electrode tab WA can be set according to actual needs. The larger the width of the electrode tab WA is, the better the effect of reducing the current density is. In some embodiments, the length of the patching line WB can be extended to increase the equivalent resistance of the patching line WB, such as making the length of the patching line WB greater than half of the length of the signal distribution line DSW. In some embodiments, the patching line WB is arranged basically around the light-emitting electrode AND, for example, the length of the patching line WB is 90% of the length of the signal distribution line DSW.

In some embodiments, as shown in FIG. 10, the extension trajectory of the patching line WB is the same as the signal distribution line DSW, and the patching line WB is arranged basically the light-emitting electrode AND, which allows the patching line WB to have the maximum length. In this case, the electrode tab WA can be designed to have a larger width to reduce the density of the current flowing into the signal distribution line DSW. In some embodiments, the width of the electrode tab WA is 5-10 times the width of the patching line WB.

In some embodiments, as shown in FIGS. 2 and 3, the automotive light-emitting panel can also include an encapsulation layer FEE to protect each light-emitting device DD. The encapsulation layer FEE can be a thin film encapsulation layer, an encapsulation cover plate, or an encapsulation color filter.

In some embodiments of the present disclosure, the position and the shape of each light-emitting unit PIX of the automotive light-emitting panel can be specifically defined. For example, the shape of each light-emitting device DD can be directly defined, or the shape of each subunit of each light-emitting device DD can be directly defined. In this way, the automotive light-emitting panel can present a more delicate pattern while emitting light, overcoming problems such as insufficient delicacy, low resolution, and uneven brightness distribution caused by scattered light sources of high brightness (such as scattered light-emitting diodes), and achieving better lighting effects, especially achieving better visual effects.

In some embodiments of the present disclosure, the size of a single light-emitting unit PIX is 0.5-2 cm. In some embodiments, the size of the light-emitting unit PIX can be a maximum of a length, a width, a diameter, and other dimensions of the light-emitting unit PIX. In some embodiments, the size of a single light-emitting unit PIX is 1 cm.

According to some embodiments of the present disclosure, a single light-emitting device DD can include multiple subunits, and each subunit has a size ranging from 200 to 400 microns. In some embodiments, the size of the subunit of the light-emitting device DD can be a maximum of a length, a width, a diameter, and other dimensions of the subunit. In some embodiments, the size of the subunit can be 300 microns.

Embodiments of the present disclosure also provide a light-emitting device, which includes any of the automotive light-emitting panels described in the aforementioned embodiments. The light-emitting device can be an ambient light in vehicle, a tail light in vehicle, or other types of light-emitting devices for vehicle or onboard. Due to the fact that the light-emitting device has any of the automotive light-emitting panels described in the above embodiments, it has the same beneficial effect, which will not be repeated herein.

After considering the specification and practices of the invention disclosed herein, those skilled in the art will easily come up with other implementation solutions of the present disclosure. The present disclosure aims to cover any variations, uses, or adaptive changes of the present disclosure, which follow the general principles of the present disclosure and include common knowledge or commonly used technical means in the art that are not disclosed in the present disclosure. The specification and embodiments are only considered exemplary, and the true scope and spirit of the present disclosure are defined by appended claims.

1. An automotive light-emitting panel, comprising at least one light-emitting unit arranged on a side of a base substrate, wherein the light-emitting unit comprises a light-emitting device and a signal distribution line driving the light-emitting device, and the light-emitting device comprises a light-emitting electrode, a light-emitting region definition layer, an organic light-emitting layer, and a common electrode that are sequentially stacked on the side of the base substrate: and
wherein the light-emitting unit further comprises a patching line, wherein the signal distribution line is electrically connected to the light-emitting electrode of the light-emitting device through the patching line, and a sheet resistance of the patching line is greater than a sheet resistance of the signal distribution line.

2. The automotive light-emitting panel according to claim 1, wherein the signal distribution line is arranged around the light-emitting electrode.

3. The automotive light-emitting panel according to claim 1, wherein a width of the patching line is smaller than a width of the signal distribution line.

4. The automotive light-emitting panel according to claim 1, wherein an orthographic projection of the patching line on the base substrate is located within an orthographic projection of the signal distribution line on the base substrate.

5. The automotive light-emitting panel according to claim 1, wherein the patching line and the light-emitting electrode are arranged in the same layer.

6. The automotive light-emitting panel according to claim 1, further comprising an inorganic insulation layer covering the signal distribution line, wherein the inorganic insulation layer comprises an opening groove that exposes at least part of the signal distribution line, and the patching line is electrically connected to the signal distribution line through the opening groove.

7. The automotive light-emitting panel according to claim 1, wherein a length of the patching line is not less than half of a length of the signal distribution line.

8. The automotive light-emitting panel according to claim 1, wherein the patching line comprised in the light-emitting unit comprises multiple patching lines, first ends of the patching lines are electrically connected to the signal distribution line, and second ends of the patching lines are electrically connected to different positions on an edge of the light-emitting electrode.

9. The automotive light-emitting panel according to claim 8, wherein first ends of at least two of the patching lines are electrically connected to each other and are electrically connected to a same position on the signal distribution line.

10. The automotive light-emitting panel according to claim 8, wherein the patching lines are electrically connected to different positions on the signal distribution line.

11. The automotive light-emitting panel according to claim 1, wherein the light-emitting unit further comprises an electrode tab connected to the light-emitting electrode, wherein a size of a connection between the electrode tab and the light-emitting electrode is greater than a width of the patching line, and the patching line is electrically connected to the electrode tab.

12. The automotive light-emitting panel according to claim 11, wherein the electrode tab and the light-emitting electrode are arranged in the same layer.

13. The automotive light-emitting panel according to claim 11, wherein an edge of the electrode tab comprises a first edge connected to the patching line and a second edge connected to the light-emitting electrode, and the first edge is not adjacent to the second edge.

14. The automotive light-emitting panel according to claim 11, further comprising an inorganic insulation layer covering the signal distribution line, wherein the electrode tab overlaps with the signal distribution line, and the electrode tab is insulated with the signal distribution line through the inorganic insulation layer.

15. The automotive light-emitting panel according to claim 11, wherein the electrode tab connected to the light-emitting electrode comprises multiple electrode tabs, and the electrode tabs are connected to different positions on an edge of the light-emitting electrode.

16. The automotive light-emitting panel according to claim 15, wherein the electrode tabs connected to the light-emitting electrode are distributed symmetrically to a symmetrical center, and the symmetrical center coincides with a center of the light-emitting electrode; or
the electrode tabs connected to the light-emitting electrode are distributed symmetrically to a rotational center, and the rotational center coincides with a center of the light-emitting electrode.

17-18. (canceled)

19. The automotive light-emitting panel according to claim 15, wherein the light-emitting electrode comprises a polygonal light-emitting electrode, and the electrode tabs are arranged adjacent to a top corner of the light-emitting electrode.

20. The automotive light-emitting panel according to claim 1, further comprising an inorganic insulation layer covering the signal distribution line, wherein the light-emitting region definition layer comprises multiple light-emitting openings that expose the light-emitting electrode, the inorganic insulation layer comprises a light output groove, and orthographic projections of the light-emitting openings on the base substrate are located within an orthographic projection of the light output groove on the base substrate.

21. The automotive light-emitting panel according to claim 1, wherein a material of the signal distribution line is metal or conductive metal oxide, and a material of the light-emitting electrode is conductive metal oxide.

22. A light-emitting apparatus comprising the automotive light-emitting panel according to claim 1.
